(19) United States
(12) Patent Application Publication
(10) Pub. No.: US 2026/0156890 A1
(43) Pub. Date: Jun. 4, 2026

(54) SUBSTRATE PROCESSING METHOD AND SUBSTRATE PROCESSING APPARATUS

(71) Applicant: Tokyo Electron Limited, Tokyo (JP)

(72) Inventors: Tatsuo HIRASAWA, Nirasaki City (JP); Masayuki NASU, Nirasaki City (JP)

(21) Appl. No.: 19/396,678

(22) Filed: Nov. 21, 2025

(30) Foreign Application Priority Data
Dec. 3, 2024 (JP) 2024-210702

(51) Int. Cl. H01L 21/285; C23C 10/04; C23C 10/08; C23C 16/04; C23C 16/14; C23C 16/50; C23C 16/56

(52) U.S. Cl. CPC H10D 64/0112; C23C 10/04; C23C 10/08; C23C 16/045; C23C 16/14; C23C 16/50; C23C 16/56

(57) ABSTRACT

A substrate processing method includes: forming a first metal film, composed of a metal other than Ru, on an Si-containing layer exposed on a surface of a substrate; and supplying an Si element to the substrate, and forming a metal silicide film from the Si element and the first metal film.

### CROSS-REFERENCE TO RELATED APPLICATION

This application is based upon and claims the benefit of priority from Japanese Patent Application No. 2024-210702, filed on Dec. 3, 2024, the entire contents of which are incorporated herein by reference.

### TECHNICAL FIELD

The present disclosure relates to a substrate processing method and a substrate processing apparatus.

### BACKGROUND

In manufacturing semiconductor devices, to provide a wiring layer, various metal films are formed after a recess is formed on a surface of a semiconductor wafer serving as a substrate (hereinafter referred to as “substrate”). In order to reduce a contact resistance between the wiring layer and an Si (silicon)-containing layer of the substrate, it is known to form a silicide by forming a metal film such as a Ti (titanium) film on a bottom of the recess.

Patent Document 1 describes forming a wiring by depositing Ti, through sputtering, on a bottom of a connection hole provided in a surface of a substrate, then depositing Ti, through plasma CVD, in the connection hole, and further filling the connection hole with Al (aluminum).

### PRIOR ART DOCUMENTS

### Patent Documents

Patent Document 1: Japanese Laid-Open Patent Publication No. H10-223570

### SUMMARY

According to one embodiment of the present disclosure, a substrate processing method includes: forming a first metal film, composed of a metal other than Ru, on an Si-containing layer exposed on a surface of a substrate; and supplying an Si element to the substrate, and forming a metal silicide film from the Si element and the first metal film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional side view illustrating a substrate surface layer before processing in an embodiment and a comparative embodiment.

FIG. 2A is a partial cross-sectional view of the substrate surface layer changed by processing of the comparative embodiment.

FIG. 2B is a partial cross-sectional view of the substrate surface layer changed by processing of the comparative embodiment.

FIG. 2C is a partial cross-sectional view of the substrate surface layer changed by processing of the comparative embodiment.

FIG. 3 is a longitudinal cross-sectional side view illustrating the substrate surface layer after processing of the comparative embodiment.

FIG. 4A is a partial cross-sectional view of a substrate W changed by processing of the embodiment.

FIG. 4B is a partial cross-sectional view of the substrate W changed by processing of the embodiment.

FIG. 5A is a partial cross-sectional view of the substrate W changed by processing of the embodiment.

FIG. 5B is a partial cross-sectional view of the substrate W changed by processing of the embodiment.

FIG. 5C is a partial cross-sectional view of the substrate W changed by processing of the embodiment.

FIG. 6 is a longitudinal cross-sectional side view illustrating the substrate surface layer after processing of the embodiment.

FIG. 7 is a plan view illustrating a substrate processing apparatus for performing processing of the embodiment.

FIG. 8 is a longitudinal cross-sectional side view illustrating a processing module in the substrate processing apparatus.

FIG. 9 is a time chart illustrating supply and shutoff of each gas in the processing module.

FIG. 10 is a first SEM image illustrating a surface layer of a bare wafer after Evaluation Test 1.

FIG. 11 is a second SEM image illustrating a surface layer of a bare wafer after Evaluation Test 1.

FIG. 12 is a longitudinal cross-sectional view illustrating a change in the substrate surface layer before and after Evaluation Test 2.

FIG. 13 is a graph illustrating results of Evaluation Test 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Formation of Metal Silicide Film in Comparative Embodiment>

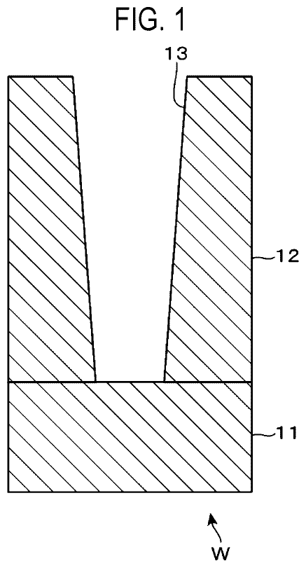

Before describing a method of forming a metal silicide film according to the present disclosure, processing of a comparative embodiment related to tasks of the present disclosure is described. FIG. 1 is a diagram illustrating a substrate surface layer before processing of the present disclosure or the comparative embodiment. On a surface layer of a substrate W on which processing of the present disclosure and the comparative embodiment is performed, an Si layer 11 as an Si-containing layer is provided and an SiN (silicon nitride) layer 12 is stacked on the Si layer 11. Further, a through-hole such as a hole or trench is formed in the SiN layer 12, thereby forming a recess 13 that is open at the surface of the substrate W, with the Si layer 11 exposed at a bottom surface of the recess 13. A sidewall of the recess 13 is formed by the SiN layer 12. Further, as the processing of the present disclosure and the comparative embodiment, a Ti film (first metal film) 14 is formed on the bottom of the recess 13, and a series of processing for silicidizing the Ti film 14 by heating is performed. In addition, the substrate W is, for example, a semiconductor wafer.

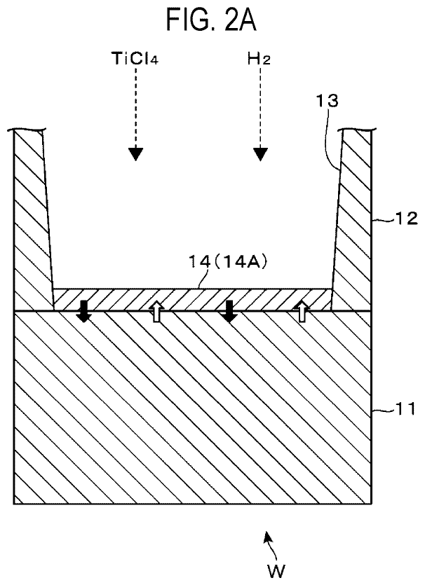

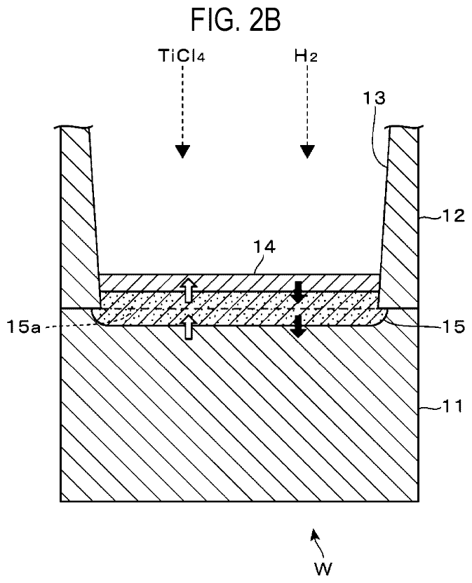

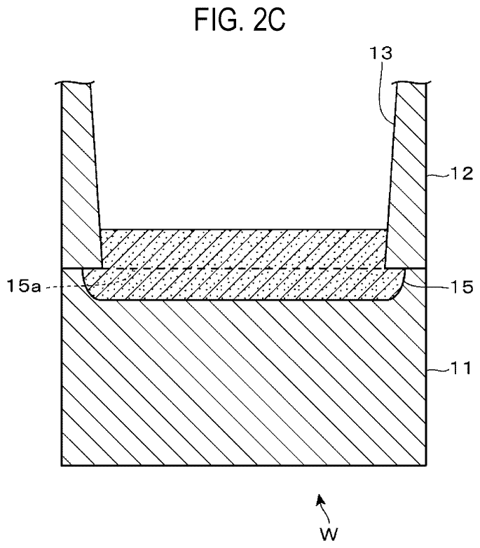

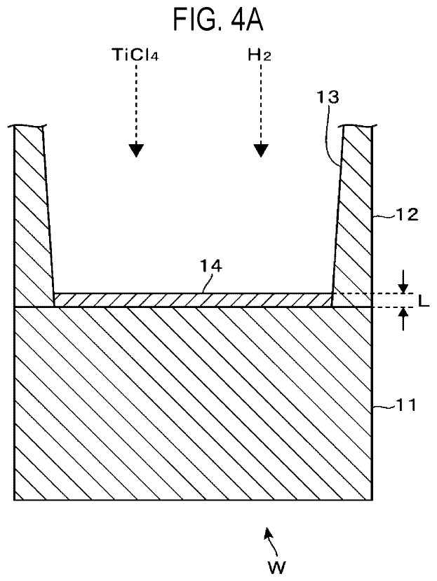

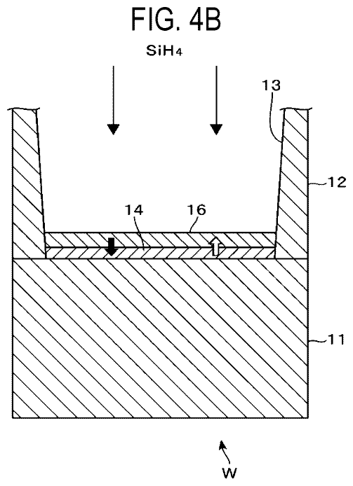

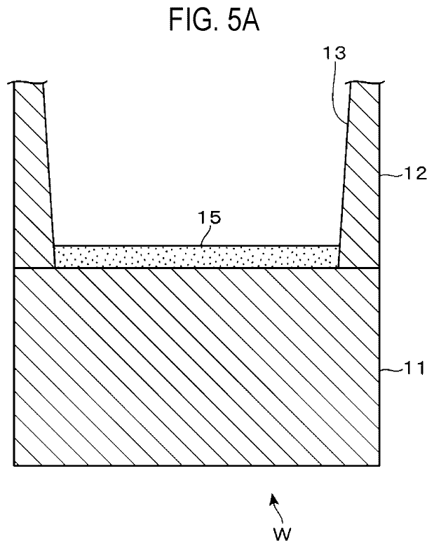

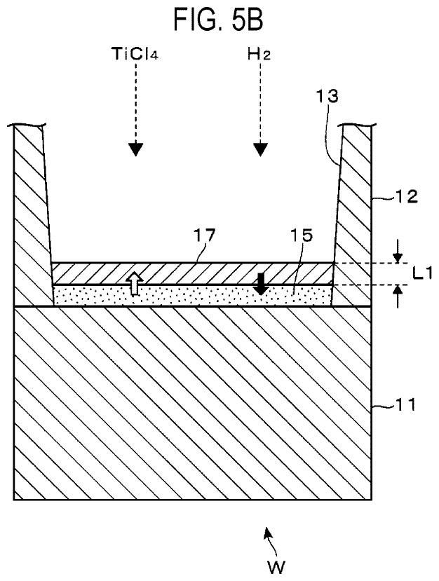

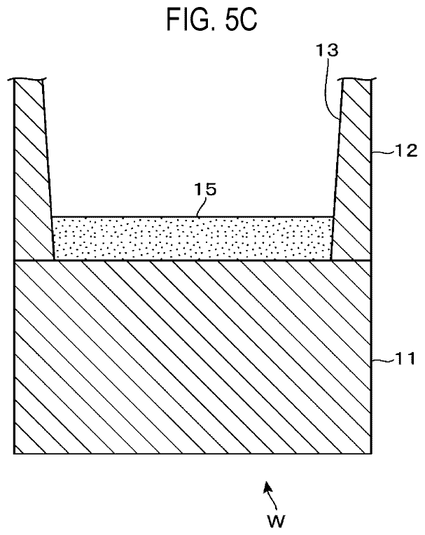

FIGS. 2A to 2C are partial cross-sectional views of the substrate surface layer changed by processing of the comparative embodiment, in which black arrows indicate diffusion of Ti (titanium), and white arrows indicate diffusion of Si. In FIGS. 2B and 2C, the dotted line indicates a surface position of the Si layer 11 before formation of the Ti film 14, i.e., an interface position between the Ti film 14 and the Si layer 11 at an initial stage of Ti film formation. The same applies to FIGS. 4A to 5C illustrating the present disclosure, which is described later. Further, the interface between the Ti film 14 and the Si layer 11 at the initial stage of Ti film formation, indicated by the dotted line, is sometimes simply referred to as an initial interface.

First, Ti forming the Ti film 14 is gradually deposited, by plasma CVD, at the bottom of the recess 13 of the substrate W (FIG. 2A). At this time, between the Ti film 14 and the Si layer 11 in contact with the Ti film 14, Ti and Si respectively constituting the Ti film 14 and the Si layer 11 mutually diffuse through the initial interface according to a concentration gradient between Ti and Si as a result of heating of the substrate W during the Ti film formation (FIG. 2B). That is, Ti constituting the Ti film 14 diffuses into the Si layer 11, and Si constituting the Si layer 11 diffuses into the Ti film 14. When a deposition amount of Ti is large (i.e., when the Ti film 14 is relatively thick), an amount of Ti diffusing into the Si layer 11 becomes relatively large, and the Ti moves relatively extensively downward and laterally in the Si layer 11. Accordingly, as illustrated in FIG. 2C, a TiSi film 15 is formed such that the TiSi film 15 erodes the Si layer 11 to a relatively large extent. More specifically, the TiSi film 15 is formed such that its lower end is spaced relatively further downward than the initial interface and its side edge is located below the SiN layer 12. Accordingly, it may be said that a consumption amount of the Si layer 11 is relatively large in forming the TiSi film 15.

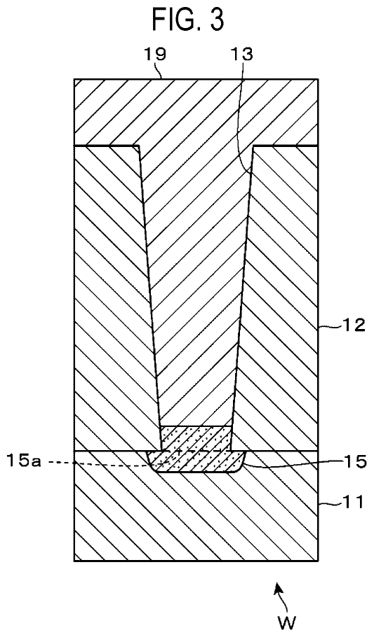

FIG. 3 is a diagram illustrating the substrate surface layer after the processing of the comparative embodiment. The completed TiSi film 15 has relatively high conductivity, and constitutes a contact portion between a wiring layer 19 to be formed later and the Si layer 11. Since the TiSi film 15 is formed such that the Si layer 11 is relatively largely eroded by the formation of the TiSi film 15, there is a possibility that electrical performance defects of semiconductor devices manufactured from the substrate W, such as an increase in leakage current, may occur (FIG. 3).

### <Formation of Metal Silicide Film in Present Disclosure>

FIGS. 4A to 5C are partial cross-sectional views of the substrate W changed by processing of the present disclosure (processing of the embodiment). The processing of the embodiment prevents erosion of the Si layer 11 by the TiSi film 15 as described above. Each of the following processing is performed by accommodating the substrate W in a processing container, the interior of which is exhausted to a vacuum pressure, and supplying respective gases into the processing container. The substrate W is heated to a predetermined temperature suitable for processing.

For example, a TiCl₄ (titanium tetrachloride) gas, H₂ (hydrogen) gas, and Ar (argon) gas are supplied to the substrate W illustrated in FIG. 1 inside the processing container, and by plasma CVD, which involves forming these gases into plasma, the Ti film 14 is formed on the Si layer 11 at the bottom of the recess 13 (FIG. 4A). A formation period of the Ti film 14 is set relatively short so that a thickness of the Ti film 14 is relatively small, although it depends on an apparatus configuration for film formation and other processing conditions. For example, the Ti film 14 is formed such that a thickness L with respect to the initial interface is 5 nm or less. It may be said that a concentration of Ti on the Si layer 11 is low because of the small thickness of the Ti film 14. Therefore, diffusion of Si and Ti caused by a concentration gradient between the Ti film 14 and the Si layer 11 is difficult to occur. Accordingly, even if the Ti film 14 is formed, the formation of the TiSi film 15, and consequently the erosion of the Si layer 11 by the TiSi film 15 are prevented. In addition, although the thickness L of the Ti film 14 with respect to the initial interface is described as being, for example, 5 nm or less, more specifically, the thickness L of the Ti film 14 or the TiSi film 15 with respect to the initial interface is 5 nm or less since it is also conceivable that a portion of the Ti film 14 changes to the TiSi film 15.

Subsequently, as illustrated in FIG. 4B, for example, an SiH₄ (monosilane) gas is supplied as an Si supply gas into the processing container, and CVD is performed to stack an Si film 16 on the Ti film 14. By heating of the substrate W for this film formation, mutual diffusion between Ti and Si according to a concentration gradient occurs between the Ti film 14 and the Si film 16. That is, Ti contained in the Ti film 14 diffuses into the Si film 16, and Si contained in the Si film 16 diffuses into the Ti film 14, so that the TiSi film 15 is formed from each of the Ti film 14 and the Si film 16. In other words, the Ti film 14 is silicidized by Si of the Si film 16 (FIG. 5A).

In addition, the Si film 16 is not limited to being formed so as to cover the entire Ti film 14. Further, Si may be deposited on the Ti film 14 in such a small amount that no film is formed, but in this description, it is assumed that processing proceeds in a state where the Si film 16 is formed so as to cover the entire Ti film 14, as illustrated in FIG. 4B.

Thus, in the processing of the embodiment, a supply source of Si for forming the TiSi film 15 is derived from the Si supply gas containing an Si element. In addition, when mutual diffusion of Ti and Si occurs between the Si film 16 formed by the Si supply gas and the Ti film 14, mutual diffusion of Ti and Si may also occur between the Ti film 14 and the Si layer 11. In other words, even in the processing of the embodiment, the Si layer 11 may serve as a supply source of Si for forming the TiSi film 15. However, since the concentration of Si in the Ti film 14 is increased by Si supplied from the Si film 16 to the Ti film 14, the mutual diffusion of Ti and Si caused by the above-mentioned concentration gradient between the Ti film 14 and the Si layer 11 is suppressed. Therefore, in the processing of the embodiment, the TiSi film 15 is formed on the initial interface in such a way that the erosion of the Si layer 11 is suppressed.

Thereafter, a TiCl₄ gas, H₂ gas, and Ar gas are supplied into the processing container, and by forming these gases into plasma, a Ti film 17 is formed so as to be stacked on the TiSi film 15 (FIG. 5B). By heating of the substrate W using a heating mechanism of the processing apparatus or by plasma heating during this film formation, Ti constituting the Ti film 17 diffuses into the TiSi film 15, and Si constituting the TiSi film 15 diffuses into the Ti film 17, so that the Ti film 17 is also silicidized, thereby becoming the TiSi film 15. That is, a thickness of the TiSi film 15 increases (FIG. 5C).

In addition, since the thickness L of the Ti film 14 is made small to prevent the erosion of the Si layer 11 by the TiSi film 15 as mentioned above, a thickness L1 of the Ti film 17 illustrated in FIG. 5B is, for example, greater than the thickness L of the Ti film 14. In addition, since the Ti film 17 changes to the TiSi film 15, the thickness L1 of the Ti film 17 is, more specifically, an increase in the thickness of the TiSi film 15 from an end point in time of the formation of the Si film 16 to an end point in time of the formation of the Ti film 17.

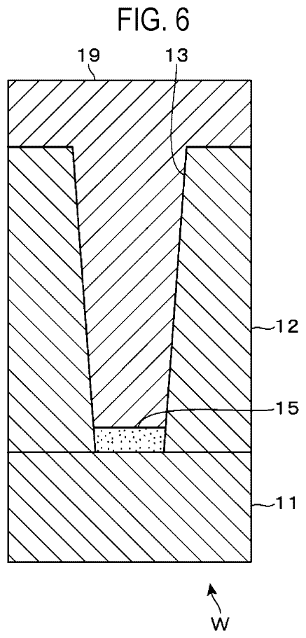

After a sufficient thickness of the TiSi film 15 is formed as illustrated in FIG. 5C, a film formation gas for metal filling is supplied into the processing container. Therefore, the wiring layer 19, which is a second metal film composed of, for example, Ru (ruthenium), is formed on the TiSi film 15 so as to fill the recess 13 (FIG. 6).

By the processing of the embodiment described above, it is possible to form the TiSi film 15 of a sufficient thickness on the substrate W while preventing the erosion of the Si layer 11 by the TiSi film 15. Since the TiSi film 15, which serves as a contact portion, has a sufficient film thickness, good electrical connection between the wiring layer 19 and the Si layer 11 may be achieved, and the electrical performance defects as described above may be prevented.

A supplementary description is given below regarding the processing of the embodiment described with reference to FIGS. 4A to 5C. As described above, the processing of the embodiment uses Si supplied from a silane gas for forming the TiSi film 15, thereby suppressing Si in the Si layer 11 from being consumed in the formation of the TiSi film 15. A timing of supplying the Si supply gas is after the Ti film 14 has been formed. This is because, as illustrated in an evaluation test described later, Si in the silane gas is difficult to be adsorbed onto the Si layer 11 even if the silane gas is supplied onto the Si layer 11. However, if the Ti film 14 is formed on the Si layer 11, Si is relatively efficiently adsorbed onto the Ti film 14 to serve as a material for forming the TiSi film 15. However, if Ti is excessively deposited on the Si layer 11 (i.e., if the Ti film 14 becomes thick), the erosion of the Si layer 11 by the TiSi film 15 becomes relatively large, as described in the processing of the comparative embodiment. Therefore, in the processing of the embodiment, the silane gas is supplied to the substrate W in a state where the thin Ti film 14 is formed, so that Si contained in the gas serves as the material for forming the TiSi film 15.

By the way, if Ti sufficiently diffuses from the Ti film 14 into the Si film 16 by formation of the Si film 16 described with reference to FIG. 4B and heating of the substrate W accompanying the film formation, and if the thickness of the TiSi film 15 formed by the formation of the Si film 16 is sufficient, the formation of the Ti film 17 illustrated in FIGS. 5B and 5C need not be performed. However, if the Si film 16 is formed with a thickness that allows sufficient diffusion of Ti, the thickness of the TiSi film becomes relatively small. Accordingly, at a point in time when the formation of the Si film 16 is completed and the TiSi film 15 is formed from the Si film 16 (at the point in time illustrated in FIG. 5A), there is a concern that a sufficient thickness of the TiSi film 15 may not be ensured. The formation of the Ti film 17 is desirable for making the TiSi film 15 sufficiently thick. That is, it is desirable to perform the formation of the first metal film (Ti film) multiple times, such that the Si supply gas for forming the Si film 16 is supplied between successive Ti film formation steps, thereby forming a metal silicide film from each first metal film.

In addition, after the formation of the Ti film 17, the Si film 16 may be formed again, so that Ti constituting the Ti film 17 diffuses into the Si film 16 and the TiSi film 15 is further thickened. That is, the formation of the Ti film and the formation of the Si film may be alternately performed, and each of the Ti film formation and the Si film formation may be performed multiple times. In addition, in such alternate formation of the Ti film and the Si film, the Ti film may be formed last, or the Si film may be formed last.

By the way, when supplying Si to the substrate W to cause adsorption, SiH₄ (monosilane) has been described as the Si supply gas, which is a compound containing an Si element, but the present disclosure is not limited to using the SiH₄ gas, and for example, Si₂H₆ (disilane) and the like may be used. However, when the Si₂H₆ gas is used, an unnecessary Si film tends to be formed on the SiN layer 12 constituting the sidewall of the recess 13. That is, selectivity of film formation of the Si film between the Ti film 14 and the SiN layer 12 is low. On the other hand, when the SiH₄ gas is used, the Si film is selectively formed on the Ti film 14 rather than on the SiN layer 12, as illustrated in the evaluation test described later.

This is because, at a relatively high temperature, SiH₄, after being adsorbed on a metal film, decomposes and produces SiH₂, which becomes a raw material for forming the Si film. In the state of SiH₄, adsorptivity to silicon-containing compounds such as the Si layer 11 and the SiN layer 12 (meaning as constituent components and not as impurities) is low. In contrast, Si₂H₆ decomposes and produces SiH₂ before adsorption on each film, and SiH₂ has relatively high adsorptivity to both metals, such as Ti, and silicon-containing compounds. Therefore, it is desirable to use SiH₄ as the Si supply gas, whereby SiH₂ may be selectively adsorbed on the Ti film 14, and film formation on the SiN layer 12 may be prevented.

In addition, in supplying the SiH₄ gas to the substrate W as described above, Si is efficiently adsorbed since the Ti film 14 is formed. Therefore, when supplying the SiH₄ gas to the substrate W, for example, a temperature of the substrate W may be set to 450 degrees C. or lower, and an internal pressure of the processing container accommodating the substrate may be set to 1 Torr or lower. In the evaluation test described later, it is confirmed that it is possible to perform the adsorption of Si onto the substrate W at such temperature and pressure. Further, it is confirmed that adsorption is possible even when the temperature of the substrate W is at 400 degrees C.

### <Substrate Processing Apparatus According to Embodiment>

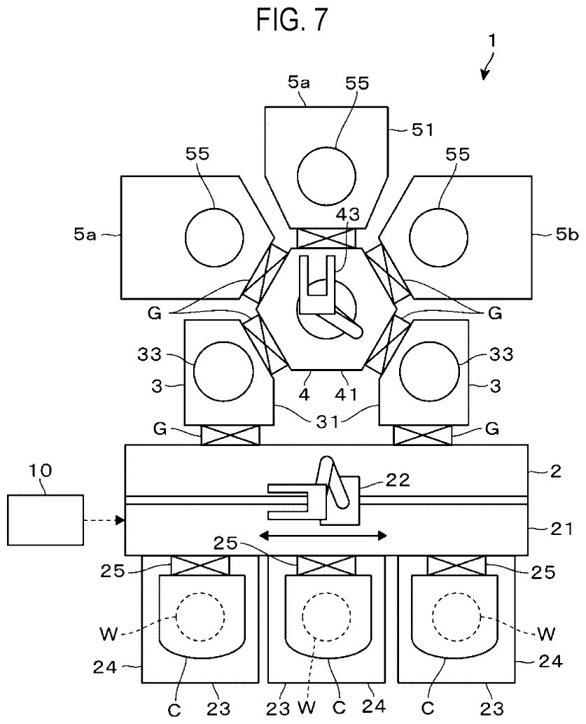

A substrate processing apparatus 1 for performing the processing of the present disclosure as described above is described below. FIG. 7 is a plan view illustrating the substrate processing apparatus. The substrate processing apparatus 1 includes processing modules 5a for performing a series of processing described in FIGS. 4A to 5C, and a processing module 5b for forming the wiring layer 19. The processing modules 5a correspond to a Ti film formation part and a metal silicide film formation part.

The substrate processing apparatus 1 is configured such that, from a front side toward a rear side, an atmospheric transport module 2, two load lock modules 3, a vacuum transport module 4, and the processing modules 5a and 5b are disposed in this order. Hereinafter, the load lock module may be referred to as “LLM.” The atmospheric transport module 2 includes a housing 21, and an interior of the housing 21 is maintained at atmospheric pressure. A transporter 22 is provided inside the housing 21. The transporter 22 is configured, for example, as a multi-joint arm capable of moving laterally. Further, the atmospheric transport module 2 includes, for example, three load ports 23 for transferring the substrate W between a transport container C and the LLM 3, and the three load ports 23 are provided side by side in a lateral direction.

Each load port 23 includes a stage 24 for the transport container C provided on a front side of the housing 21, a transport port provided at a sidewall of the housing 21 facing the transport container C on the stage 24, and a door 25 for opening or closing the transport port. In addition, the transport container C is configured to accommodate a plurality of substrates W therein and is, for example, a Front Opening Unified Pod (FOUP). The transporter 22 transports the substrate W between the transport container C and the LLM 3.

The LLM 3 includes a housing 31, and is configured to appropriately change an internal pressure of the housing 31 between atmospheric pressure and a predetermined vacuum pressure. Two transport ports are provided at the housing 31 for loading the substrate W to and from the atmospheric transport module 2 and the vacuum transport module 4, respectively, and gate valves G are provided in the respective transport ports. A stage 33 is provided inside the housing 31 for placing the substrate W thereon, and the substrate W is transferred between the stage 33 and the transporter 22 of the atmospheric transport module 2 and between the stage 33 and a transporter 43 of the vacuum transport module 4 described later.

The vacuum transport module 4 includes a housing 41, and the LLMs 3 and the processing modules 5a and 5b are connected respectively to side surfaces of the housing 41 via respective gate valves G. An interior of the housing 41 is exhausted by an exhauster (not illustrated), so at to be constantly maintained under a predetermined vacuum atmosphere during operation of the substrate processing apparatus 1. The transporter 43, which is a multi-joint arm, is provided inside the housing 41. The transporter 43 transports the substrate W between the processing modules 5a and 5b and the LLMs 3.

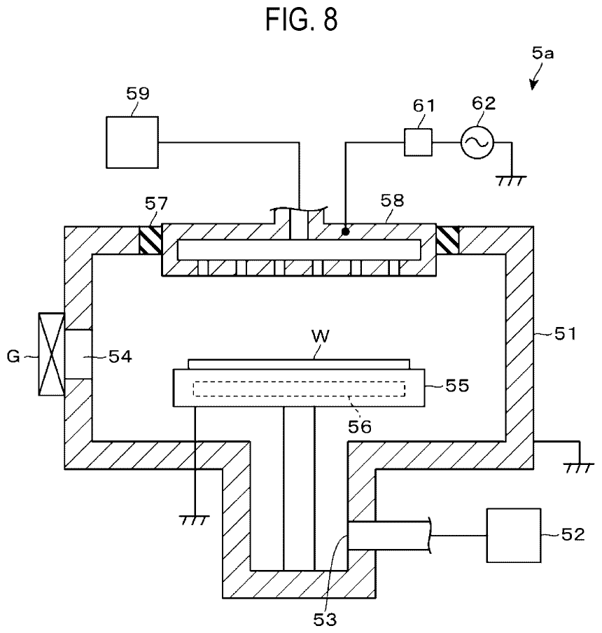

Among the respective processing modules 5a and 5b, the processing module 5a is described representatively. FIG. 8 is a longitudinal cross-sectional side view of the processing module 5a. The processing module 5a is configured to continuously supply a TiCl₄ gas, H₂ gas, and argon (Ar) gas to the surface of the substrate W to form the Ti films 14 and 17 by plasma CVD. The TiCl₄ gas is a raw material gas serving as a film formation raw material, the H₂ gas serves to eliminate influence of chlorine, and the Ar gas is a plasma generation gas. Further, the processing module 5a supplies an SiH₄ gas to the surface of the substrate W to form the Si film 16.

The processing module 5a includes a metallic processing container 51, and the processing container 51 is grounded. An exhauster 52 is connected to the processing container 51, so that exhausting is performed from an exhaust port 53 formed at a bottom wall of the processing container 51. Therefore, an interior of the processing container 51 is maintained at a predetermined vacuum pressure. Specifically, for example, during film formation (i.e., during execution of the processing of FIGS. 4A to 5C), the interior is maintained at a pressure of 133.3 Pa (1 Torr) or lower. The exhauster 52 is configured, similarly to the exhauster of the LLM 3, to include a valve or a vacuum pump, so as to be capable of adjusting an exhaust amount in the processing container 51 to maintain the interior of the processing container 51 under a vacuum atmosphere of a desired pressure. Further, the processing container 51 is provided with a transport port 54 for the substrate W, and the transport port 54 is opened or closed by the gate valve G.

A stage 55, which is circular in a plan view, is provided inside the processing container 51 for placing the substrate W thereon. A heater 56, configured, for example, with a heating wire and the like, is embedded in the stage 55 to adjust a temperature of the stage 55, for example, to 400 degrees C. to 450 degrees C. Similar to the stage 33 of the LLM 3, the stage 55 is provided with three pins, which may protrude from and retract to an upper surface of the stage, and via these pins, the substrate W may be transferred between the transporter 43 of the vacuum transport module 4 and the stage 55. The stage 55 is grounded and is disposed inside the processing container 51 by a support provided at a bottom of the processing container 51. The support includes an insulating member (not illustrated) for electrically insulating the stage 55 from the processing container 51.

At a top of the processing container 51, an opening is formed to face upward, and a shower head 58 is installed via an annular insulating member 57. The shower head 58 is connected to a gas supplier, which is described later, through a supply flow path, and encloses a gas diffusion space to which various gases are supplied from the gas supplier. In addition, through-holes to discharge various gases from the gas diffusion space into the processing container 51 are provided at a lower portion of the shower head 58. The gas supplier 59 is configured to supply a TiCl₄ gas, H₂ gas, Ar gas, and SiH₄ gas. Specifically, the gas supplier 59 includes supply sources for the respective gases, valves for switching between supply and shutoff of the respective gases into the processing container 51, and flow rate adjusters such as mass flow controllers and the like for adjusting supply flow rates of the respective gases toward a downstream side of the aforementioned supply flow path.

Further, a radio frequency power supply 62 is connected to the shower head 58 through a matcher 61 to supply radio frequency power for plasma generation. The processing module 5a constitutes a parallel-plate-type plasma processing apparatus including the shower head 58 serving as an upper electrode and the stage 55 serving as a lower electrode. In addition, by placing the substrate W on the stage 55, the substrate W is disposed in a space between the shower head 58 and the stage 55, and by supplying a TiCl₄ gas, H₂ gas, and Ar gas among the gases and applying radio frequency power, plasma is generated, decomposing the TiCl₄ gas and forming the Ti films 14 and 17. In the processing module 5a, as illustrated in test results described later, it is desirable that the Ti film 14 be formed by exposing the substrate W to the plasma-activated atmosphere as described above, for example, for 30 seconds or less, more particularly 20 seconds. Further, the Si film 16 described above is formed by the SiH₄ gas supplied from the shower head 58 without being formed into plasma. Accordingly, the formation of the Ti films 14 and 17 by the supply of TiCl₄ gas, H₂ gas, and Ar gas, and the formation of the Si film 16 by the supply of SiH₄ gas are performed at different timings.

The processing module 5b for forming the wiring layer 19 is configured to supply various gases by non-plasma CVD, and does not include the matcher 61 and the radio frequency power supply 62, and the stage 55 is not grounded. A gas supplier of the processing module 5b includes a configuration similar to that of the processing module 5a, but is configured to supply a Ru-containing gas such as a Ru₃(CO)₁₂ gas and the like to the substrate W as a film formation gas.

Returning to FIG. 7, the substrate processing apparatus 1 includes a controller 10, which is a computer. The controller 10 includes a program, a memory, and a CPU. The program incorporates instructions (individual steps) such that the above-described processing and transport of the substrate W are performed. The program is stored in a non-transitory computer-readable storage medium such as a compact disk, hard disk, magneto-optical disk, and DVD and the like, and is installed in the controller 10. The controller 10 outputs control signals to various parts of the substrate processing apparatus 1 based on the program to control operations of the respective parts.

Examples of the operations of the substrate processing apparatus 1, controlled by the control signals described above, may include the transport of the substrate W between the modules by movement of each transporter and lifting/lowering of the stage pins, the opening or closing of the gate valves G, the pressure adjustment in the housing 31 of the LLM 3 by gas supply and exhaust, the gas supply from the shower head 58 in the respective processing modules 5a and 5b, the pressure adjustment in the processing container 51, and the switching between execution and stopping of plasma processing by the on/off of the radio frequency power supply 62.

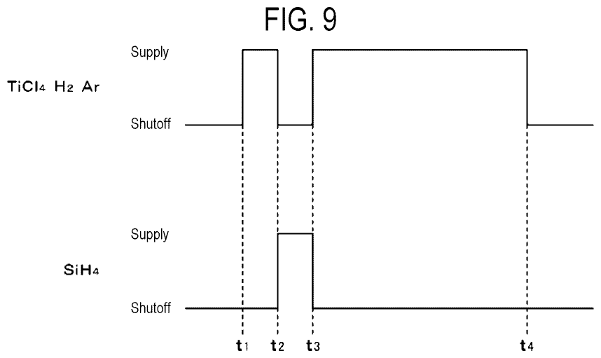

Next, the transport of the substrate W in the substrate processing apparatus 1 and the processing performed by a processing method of the present disclosure are described with reference to FIGS. 4A to 5C and a timing chart illustrated in FIG. 9. The timing chart indicates the supply and shutoff of respective gases into the processing container 51 of the processing module 5a.

First, the substrate W, including the recess 13 formed therein and accommodated in the transport container C transported to the load port 23 of the substrate processing apparatus 1, is transported in the order of the load lock module 3→the vacuum transport module 4→the processing module 5a. Then, after adjusting the internal pressure of the processing container 51 to the aforementioned pressure and adjusting the temperature of the substrate W to the aforementioned temperature, the supply of TiCl₄ gas, H₂ gas, and Ar gas and the formation of plasma from these gases by the supply of radio frequency power are performed (time t1), thereby forming a first Ti film (Ti film 14) on the surface of the substrate W (FIG. 4A).

Thereafter, the supply of TiCl₄ gas, H₂ gas, and Ar gas, as well as the supply of radio frequency power are stopped, while the supply of SiH₄ gas is started (time t2, FIG. 4B), thereby silicidizing the Ti film 14 (FIG. 5A). Next, the supply of SiH₄ gas is stopped, and the supply of TiCl₄ gas, H₂ gas, and Ar gas is performed along with the supply of radio frequency power for forming plasma from these gases (time t3). A second Ti film (Ti film 17) is then formed on the substrate W on which the TiSi film 15 has been formed (FIG. 5B), thereby increasing the thickness of the TiSi film 15. Thereafter, the supply of TiCl₄ gas, H₂ gas, and Ar gas, as well as the supply of radio frequency power are stopped (time t4). As described above, since the thickness L of the Ti film 14 is smaller than the thickness L1 of the Ti film 17, for example, a formation period of the first Ti film (period from time t1 to time t2) is shorter than a formation period of the second Ti film (period from time t3 to time t4).

Then, the substrate W on which the TiSi film 15 has been formed is transported to the processing module 5b, where the wiring layer 19 is formed (FIG. 6). The substrate W having the wiring layer 19 formed thereon is then transported to the LLM 3, and is then returned to the transport container C of the load port 23, and is finally transported to a substrate processing apparatus that performs subsequent processing such as chemical mechanical polishing (CMP). In addition, any necessary processing may be appropriately performed after the formation of the TiSi film 15 in the processing module 5a and before the formation of the wiring layer 19 in the processing module 5b. In such a case, for example, a processing module that performs the relevant processing may be provided so as to be connected to the vacuum transport module 4.

### (Modification)

In the present embodiment, an example in which the formation of the Ti films 14 and 17 and the formation of the Si film 16 are performed in the same processing module 5a (i.e., in the same processing container) has been described. In this case, undesired chemical reactions may occur between the gases supplied in the respective film formations or may occur in constituent components of the processing module 5a due to these gases. When such concerns exist, the formation of the Ti films 14 and 17 and the formation of the Si film 16 may be performed in different processing modules (i.e., in different processing containers). Further, even when such concerns do not exist, the film formations may still be performed in different processing modules. Then, in this case, a processing module for forming the Ti films 14 and 17 corresponds to a metal film formation part, while a processing module for forming the Si film 16 corresponds to a metal silicide film formation part. Then, the processing module 5a of the embodiment corresponds to a module in which the metal film formation part and the metal silicide film formation part are integrated.

Then, in the above embodiment, Si was supplied to the Ti film 14 by supplying a gas that is a compound containing an Si element, but the present disclosure is not limited thereto. For example, Si may be supplied to the Ti film 14 by another method such as sputtering or the like, but it is desirable to supply Si by supplying an SiH₄ gas, which allows effective selective film formation on the Ti film 14.

The Ti film 14 formed in the first Ti film formation processing and the Ti film 17 formed in the second Ti film formation processing need not be formed by the same film formation processing. That is, processing conditions such as the internal pressure of the processing container 51 and the flow rates of the respective gases supplied into the processing container 51 may be set differently.

A metal film formed on the substrate W, which serves as a metal film (first metal film) to be silicidized, may be a metal film other than Ru. For example, in addition to the Ti film illustrated in FIGS. 4A to 5C, films containing tungsten (W), molybdenum (Mo), and zirconium (Zr) or the like as constituent elements may be employed. In this way, the present technique is also applicable to formation of metal silicides other than TiSi. Further, the formation of the first metal film made of a metal on the substrate W may be performed by supplying a gas containing the metal to the substrate, and any suitable film formation method may be employed. Specifically, the formation of the first metal film is not limited to generating plasma within the processing container. Further, the film formation is not limited to CVD, and other film formation methods such as ALD, PVD and the like may be employed.

In the above embodiment, the SiH₄ gas is supplied to the substrate W without being formed into plasma in order to prevent the SiH₄ gas from decomposing into SiH₂ and adsorbing onto the SiN layer 12 prior to adsorption onto the Ti film 14. Although it is desirable not to form the SiH₄ gas into plasma, the gas may be formed into plasma and supplied to the substrate W. Even when a gas other than the SiH₄ gas is used as the Si supply gas, the gas may be formed into plasma and supplied to the substrate W, or may be supplied to the substrate W without being formed into plasma.

The wiring layer 19 embedded in the recess 13 of the substrate W is not limited to being composed of Ru, and may also be composed of a metal such as W, Mo, Cr (chromium) or the like, for example.

In addition, the embodiments disclosed herein should be considered to be exemplary and not limitative in all respects. The above embodiments may be omitted, replaced, modified and combined in various ways without departing from the scope and spirit of the appended claims.

### (Evaluation Test)

Hereinafter, evaluation tests performed in relation to a series of processing of the present disclosure are described.

### (Evaluation Test 1)

As Evaluation Test 1, a difference in adsorptivity of an SiH4 gas to a Ti film and an SiN film was confirmed. For bare wafers, which are two silicon substrates, a Ti film was formed on one, and an SiN film was formed on the other. The respective wafers were heated to 400 degrees C. within the processing container, and were exposed to a vacuum atmosphere of 133 Pa (1 Torr) for 150 seconds while supplying an SiH₄ gas at a flow rate of 500 sccm. Each bare wafer after such SiH₄ gas supply was subjected to SEM analysis to confirm presence or absence of an Si film.

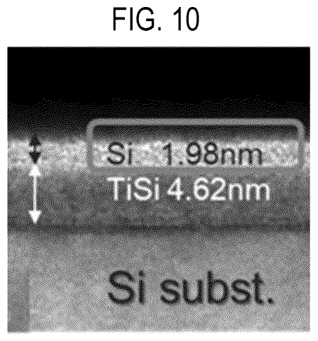

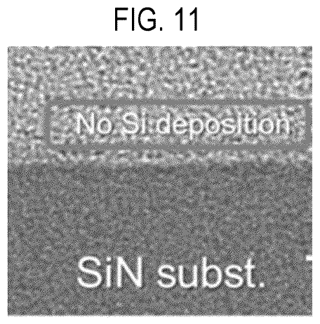

FIGS. 10 and 11 are SEM images illustrating surface layers of the respective bare wafers after the evaluation test. FIG. 10 is an SEM image of the bare wafer on which the Ti film had been formed before the SiH₄ gas supply, and FIG. 11 is an SEM image of the bare wafer on which the SiN film had been formed. As illustrated in these images, the Ti film became a TiSi film by the test, and an Si film was formed on the TiSi film. Further, no Si film was formed on the SiN film. From this, it was confirmed that an SiH₄ gas is less likely to be adsorbed on the SiN film, but is more likely to be adsorbed on a Ti-containing film such as the Ti film, and thus, facilitates the formation of the Si film.

### (Evaluation Test 2)

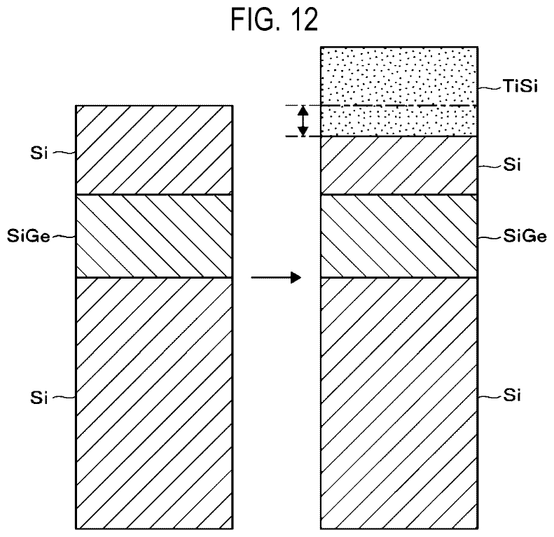

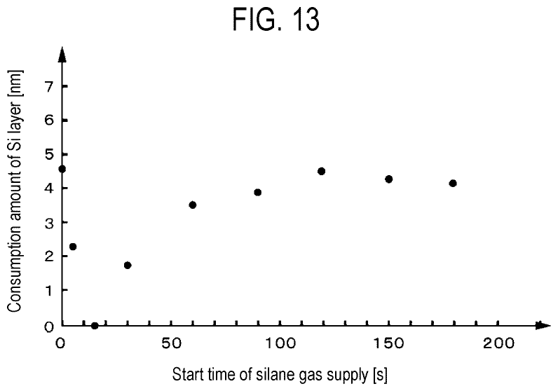

As Evaluation Test 2, a difference in expansion by erosion of an Si layer by the TiSi film 15 resulting from a difference in a timing at which an SiH₄ gas is supplied to the Ti film 14 was confirmed. FIG. 12 is a longitudinal cross-sectional view illustrating a change in the substrate surface layer before and after Evaluation Test 2. First, multiple bare wafers, which are silicon substrates, were prepared, and an SiGe (germanium) layer and an Si layer were formed by CVD on the surface of the respective bare wafers, and thereafter, a film thickness of the Si layer exposed on the surface was measured. Next, gas processing was performed on these bare wafers as illustrated in FIGS. 4A to 5C and FIG. 9. Temperatures of the bare wafers during the processing was set to 450 degrees C. The supply of SiH₄ gas to the respective bare wafers was started at different timings, as illustrated in FIG. 13. More specifically, while a period from time t1 to time t4 in the chart illustrated in FIG. 9 was the same among the bare wafers, the timing of starting the supply of SiH₄ gas at time t2 was shifted among the bare wafers, such that a period from time t1 to time t2 differed among them.

After the series of processing, a length between interfaces of the TiSi film and the SiGe layer formed on the respective bare wafers was measured, and thus a film thickness of the Si layer remaining on the respective bare wafers was measured. Then, a difference between the film thickness of the remaining Si layer in the respective bare wafers and the film thickness of the Si layer measured before the series of processing was calculated as a consumption amount of the Si layer.

FIG. 13 is a graph illustrating results of Evaluation Test 2, with the horizontal axis representing the start time of the SiH₄ gas supply (i.e., the period from time t1 to time t2) and the vertical axis representing the consumption amount of the Si layer. As illustrated in the diagram, when the start time of the SiH₄ gas supply was 0 seconds, the consumption amount of Si was 4.7 nm, the largest among the bare wafers. Then, as the start time of the SiH₄ gas supply increased, the consumption amount of Si gradually decreased, then increased, and thereafter became substantially constant. When the start time of the SiH₄ gas supply was 15 seconds, the consumption amount of Si was the lowest and became zero.

When the start time of the SiH₄ gas supply was zero or close to zero, the consumption amount of Si was relatively large. This is presumed to be because an adsorption amount of SiH₄ gas onto the Si layer of the bare wafer was low, and Si derived from the Si layer was largely used for the formation of the TiSi film 15.

The reduced consumption amount of Si according to the increased start time of the SiH₄ gas supply within the range where the start time of the SiH₄ gas supply was 15 seconds or less is presumed to be due to the fact that, as a result of the formation of a Ti film owing to an increased deposition amount of Ti on the Si layer, the adsorptivity of SiH₄ gas to the bare wafer increased, and Si derived from the SiH₄ gas was used for the formation of the TiSi film 15.

Then, the fact that the consumption amount of Si increased and thereafter became substantially constant as the start time of SiH₄ gas supply increased within the range where the start time of SiH₄ gas supply exceeded 15 seconds indicates that the Si layer of the bare wafer was used for the formation of the TiSi film 15 before the supply of SiH₄ gas. Further, it was also found that until the amount of Ti on the Si layer reached a certain level, diffusion of Ti into the Si layer increased as the amount of Ti on the Si layer increased. When the start time of SiH₄ gas supply was too long, the consumption amount of Si increased, but as illustrated in the graph, it is seen that the consumption amount of Si was relatively suppressed within the range where the start time of SiH₄ gas supply was 30 seconds or less. Accordingly, it is desirable that the start time of SiH₄ gas supply be 30 seconds or less.

Similar changes in the consumption amount of the Si layer were confirmed even when testing with other processing modules or under different processing conditions. From this, it was found that by supplying the film formation gas with a slight delay from the start of the formation of the Ti film, the SiH₄ gas may be adsorbed onto the Ti film during the growth process thereof, thereby supplying Si to the Ti film.

According to the present disclosure, when a first metal film, composed of a metal other than Ru and formed on an Si-containing layer exposed on a surface of a substrate, is silicidized, it is possible to prevent silicidation of the Si-containing layer.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
forming a first metal film, composed of a metal other than Ru, on an Si-containing layer exposed on a surface of a substrate; and
supplying an Si element to the substrate, and forming a metal silicide film from the Si element and the first metal film.

2. The substrate processing method of claim 1, wherein the Si-containing layer is an Si layer forming a bottom surface of a recess formed in the substrate,
wherein the Si element is supplied to the first metal film as a gas that is a compound containing the Si element,
wherein a sidewall of the recess is composed of a compound containing Si, and
wherein the substrate processing method further comprises filling the recess with a second metal film so that the second metal film is stacked on the metal silicide film.

3. The substrate processing method of claim 2, wherein the metal other than Ru constituting the first metal film is one of Ti, W, Mo, and Zr.

4. The substrate processing method of claim 3, wherein the metal other than Ru constituting the first metal film is Ti.

5. The substrate processing method of claim 2, wherein the sidewall of the recess is composed of a silicon nitride film.

6. The substrate processing method of claim 5, wherein the gas that is the compound containing the Si element is an SiH₄ gas.

7. The substrate processing method of claim 2, wherein the forming the first metal film is performed a plurality of times, and
wherein the supplying the Si element to the substrate is performed between the forming the first metal film and subsequently forming the first metal film, and the metal silicide film is formed from each of the first metal films.

8. A substrate processing apparatus comprising:
a metal film formation part that forms a first metal film, composed of a metal other than Ru, on an Si-containing layer exposed on a surface of a substrate; and
a metal silicide film formation part that supplies an Si element to the first metal film and forms a metal silicide film from the Si element and the first metal film.
